(19) United States
(12) Patent Application Publication
(10) Pub. No.: US 2005/0196913 A1
(43) Pub. Date: Sep. 8, 2005

(54) Floating gate memory structures and fabrication methods

(75) Inventors: Chia-Shun Hsiao, Hsinchu (TW); Yi Ding, Sunnyvale, CA (US)

Correspondence Address: MACPHERSON KWOK CHEN & HEID LLP, 1762 TECHNOLOGY DRIVE, SUITE 226, SAN JOSE, CA, 95110, US

(73) Assignee: ProMOS Technologies Inc.

(21) Appl. No.: 11/102,329

(22) Filed: Apr. 7, 2005

Related U.S. Application Data
(63) Continuation-in-part of application No. 10/266,378, filed on Oct. 7, 2002, now abandoned.

(51) Int. Cl. H01L 21/8238; H01L 21/336

(52) U.S. Cl. 438/201

(57) ABSTRACT

Dielectric regions (210) are formed on a semiconductor substrate between active areas of nonvolatile memory cells. The top portions of the dielectric region sidewalls are etched to recess the top portions laterally away from the active areas. Then a conductive layer is deposited to form the floating gates (410). The recessed portions of the dielectric sidewalls allow the floating gates to be wider at the top. The gate coupling ratio is increased as a result. Other features are also provided.

### CROSS REFERENCE TO RELATED APPLICATIONS

The present application is a continuation-in-part of U.S. patent application Ser. No. 10/266,378, filed Oct. 7, 2002, incorporated herein by reference.

### BACKGROUND OF THE INVENTION

The present invention relates to floating gate nonvolatile memories.

A floating gate nonvolatile memory cell stores information by storing an electrical charge on its floating gate. The floating gate is capacitively coupled to the control gate. In order to write the cell, a potential difference is created between the control gate and some other region, for example, the source, drain or channel region of the cell. The voltage on the control gate is capacitively coupled to the floating gate, so a potential difference appears between the floating gate and the source, drain or channel region. This potential difference is used to change the charge on the floating gate.

In order to reduce the potential difference that has to be provided between the control gate and the source, drain or channel region, it is desirable to increase the capacitance between the control and floating gates relative to the capacitance between the floating gate and the source, drain or channel region. More particularly, it is desirable to increase the “gate coupling ratio” GCR defined as C_{CG}/(C_{CG}+C_{SDC}) where C_{CG} is the capacitance between the control and floating gates and C_{SDC} is the capacitance between the floating gate and the source, drain or channel region. One method for increasing this ratio is to form spacers on the floating gate. See U.S. Pat. No. 6,200,856 issued Mar. 13, 2001 to Chen, entitled “Method of Fabricating Self-Aligned Stacked Gate Flash Memory Cell”. In that patent, the memory is fabricated as follows. Silicon substrate 104 (FIG. 1) is oxidized to form a pad oxide layer 110. Silicon nitride 120 is formed on oxide 110 and patterned to define isolation trenches 130. Oxide 110 and substrate 104 are etched, and the trenches are formed. Dielectric 210 (FIG. 2), for example, borophosphosilicate glass, is deposited over the structure to fill the trenches, and is planarized by chemical mechanical polishing (CMP). The top surface of dielectric 210 becomes even with the top surface of nitride 120. Then nitride 120 is removed (FIG. 3). Oxide 110 is also removed, and gate oxide 310 is thermally grown on substrate 104 between the isolation trenches. Doped polysilicon layer 410.1 (FIG. 4) is deposited over the structure to fill the recessed areas between the isolation regions 210. Layer 410.1 is polished by chemical mechanical polishing so that the top surface of layer 410.1 becomes even with the top surface of dielectric 210.

Dielectric 210 is etched to partially expose the edges of polysilicon layer 410.1 (FIG. 5). Then doped polysilicon 410.2 is deposited and etched anisotropically to form spacers (FIG. 6) on the edges of polysilicon 410.1. Layers 410.1, 410.2 provide the floating gates.

As shown in FIG. 7, dielectric 710 (oxide/nitride/oxide) is formed on polysilicon 410.1, 410.2. Doped polysilicon layer 720 is deposited on dielectric 710 and patterned to provide the control gates.

Spacers 410.2 increase the capacitance between the floating and control gates by more than the capacitance between the floating gates and substrate 104, so the gate coupling ratio is increased.

### SUMMARY

This section is a brief summary of some features of the invention. The invention is defined by the appended claims which are incorporated into this section by reference.

In some embodiments of the present invention, the gate coupling ratio is increased by making the trench dielectric regions 210 more narrow at the top (see FIG. 14 for example). Therefore, the floating gate polysilicon layer is wider at the top (see FIG. 15). This increased width improves the gate coupling ratio. A single polysilicon layer is sufficient to form the floating gates with the increased gate coupling ration, though multiple polysilicon layers can also be used. Steps are also taken to reduce current leakage at the top edges of the trenches by ensuring that the dielectric 210 overlaps the top edges.

Other features are described below.

### BRIEF DESCRIPTION OF THE DRAWINGS

FIGS. 1-7 show cross sections of prior art nonvolatile memory structures in the process of fabrication.

FIGS. 8, 9A-9C, 10-16 show cross sections of nonvolatile memory structures in the process of fabrication according to the present invention.

FIG. 17 is a circuit diagram of a memory array according to the present invention.

FIG. 18 is a top view of the memory of FIG. 17.

FIGS. 19A, 19B show cross sections of the memory of FIG. 17.

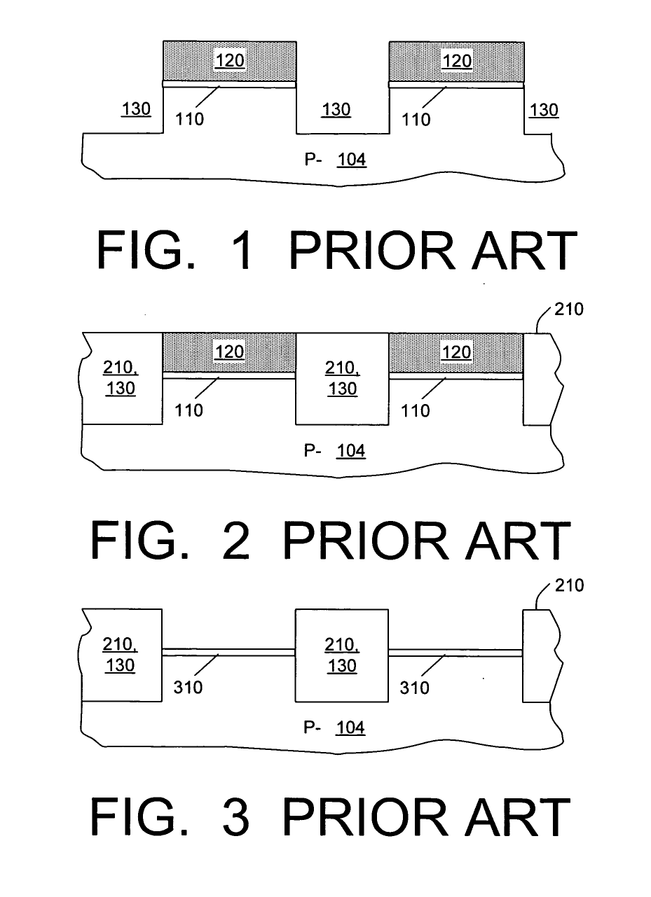

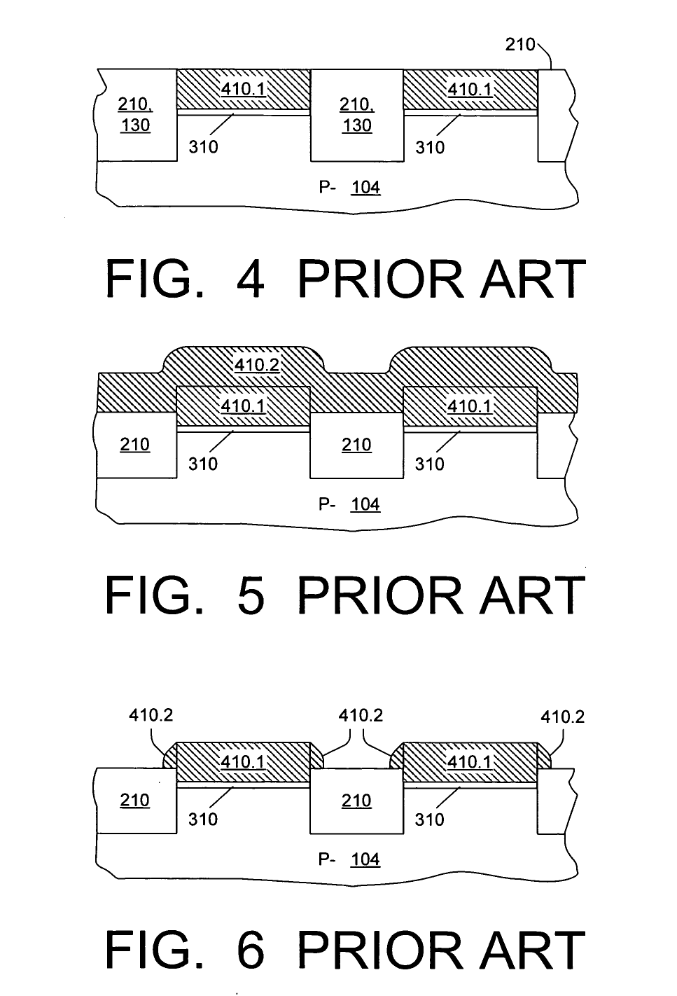

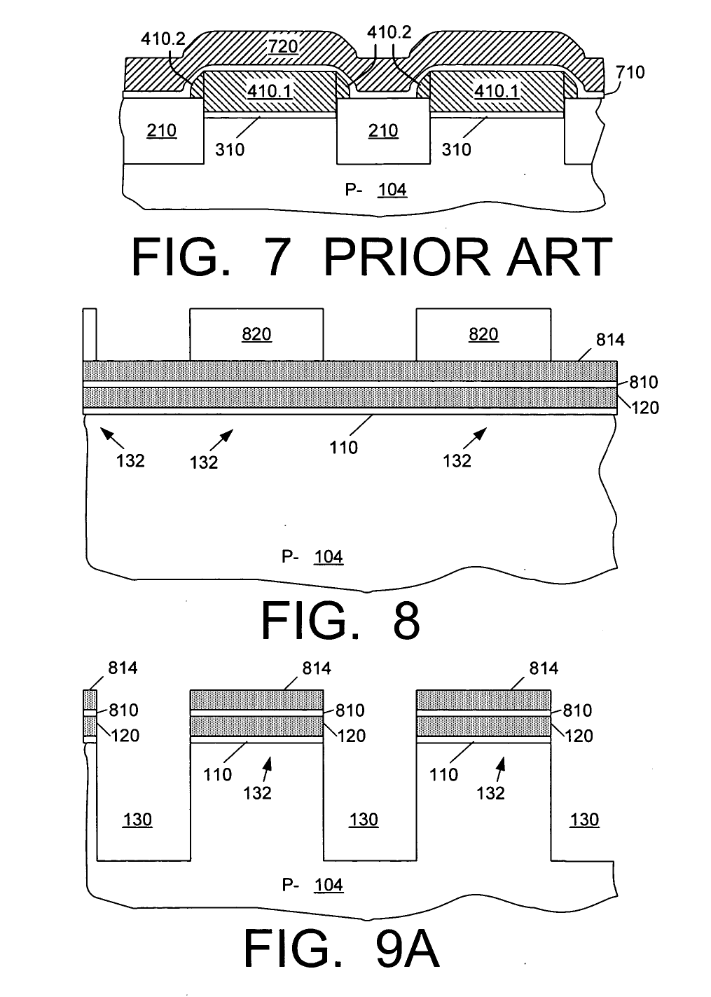

The following table describes some reference numerals used in the drawings.
104 . . . substrate
110 . . . pad oxide
120 . . . silicon nitride
130 . . . isolation trenches
210 . . . trench dielectric
310 . . . gate oxide
410, 410.1, 410.2 . . . floating gate layers
710 . . . dielectric
720 . . . control gates
810 . . . silicon dioxide
814 . . . silicon nitride
820 . . . photoresist
1720 . . . wordlines
1820 . . . source line regions
1830 . . . silicon nitride
1840 . . . stack structures
1850 . . . dielectric

### DESCRIPTION OF PREFERRED EMBODIMENTS

This section describes some embodiments to illustrate the invention. The invention is not limited to these embodiments. The materials, conductivity types, layer thicknesses and other dimensions, circuit diagrams, and other details are given for illustration and are not limiting.

FIG. 8 illustrates the beginning stages of fabrication of a memory array according to one embodiment of the invention. An isolated doped region of type P− is formed in monocrystalline semiconductor substrate 104 as described, for example, in U.S. Pat. No. 6,355,524 issued Mar. 12, 2002 to H. T. Tuan et al. and incorporated herein by reference. This region is isolated by P-N junctions (not shown). Other isolation techniques, and non-isolated regions, can also be used.

Silicon dioxide layer 110 (pad oxide) is formed on substrate 104 by thermal oxidation or some other technique to an exemplary thickness of 9 nm. Silicon nitride 120 is deposited on oxide 110. An exemplary thickness of this layer is 90 nm. Another silicon dioxide layer 810 is formed on nitride 120. An exemplary thickness of this layer is 5 nm. Silicon nitride 814 is deposited on oxide 810, to a thickness of 90 nm.

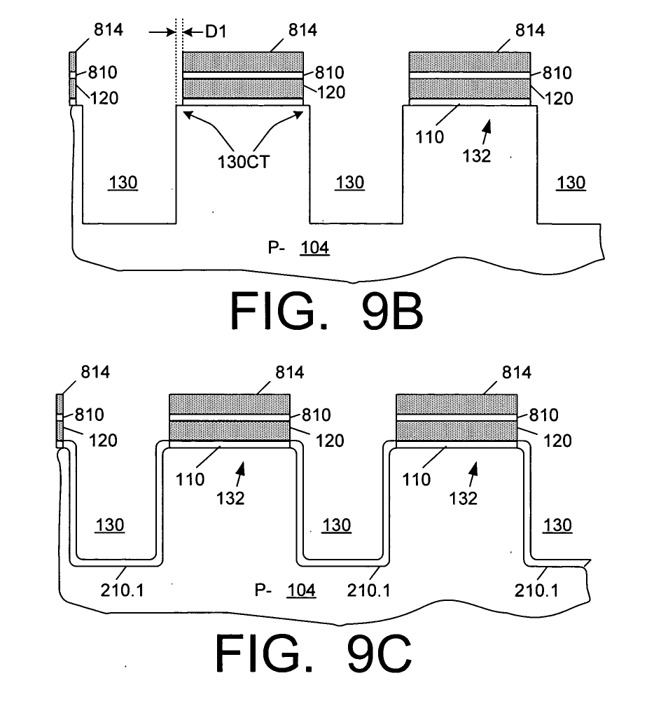

Photoresist mask 820 is formed on layer 814 by means of photolithography. This mask defines (and exposes) isolation trenches 130 (FIG. 9A). This mask also defines (and covers) substrate areas 132 not occupied by the isolation trenches. Areas 132 include the active areas (the source, drain and channel regions) of the memory cells.

Layers 814, 810, 120, 110, and substrate 104 are etched where exposed by the mask, to form the isolation trenches. (Resist 820 can be removed immediately after the etch of nitride 814 or at a later stage.)

Nitride/oxide stacks 110, 120, 810, 814 are subjected to a wet etch to recess the vertical edges of these stacks away from the top edge corners 130TC of trenches 130. See FIG. 9B. In some embodiments, the nitride/oxide stack is recessed by a distance D1 of about 10˜5 nm. A wet etch can be used with an HF/glycerol etchant to etch the nitride and the oxide at the same time. This etch is selective to silicon. Other etches are also possible. Recessing the stack edges leads to a reduced aspect ratio of the holes that will be filled with dielectric 210. The lower aspect ratio facilitates filling these holes. Note U.S. Pat. No. 6,743,675 issued to Yi Ding on Jun. 1, 2004, and U.S. Pat. No. 6,838,342 issued to Yi Ding on Jan. 4, 2005, both incorporated herein by reference. Recessing the stack edges will also help protect the STI dielectric 210 at the trench corners 130TC as explained below.

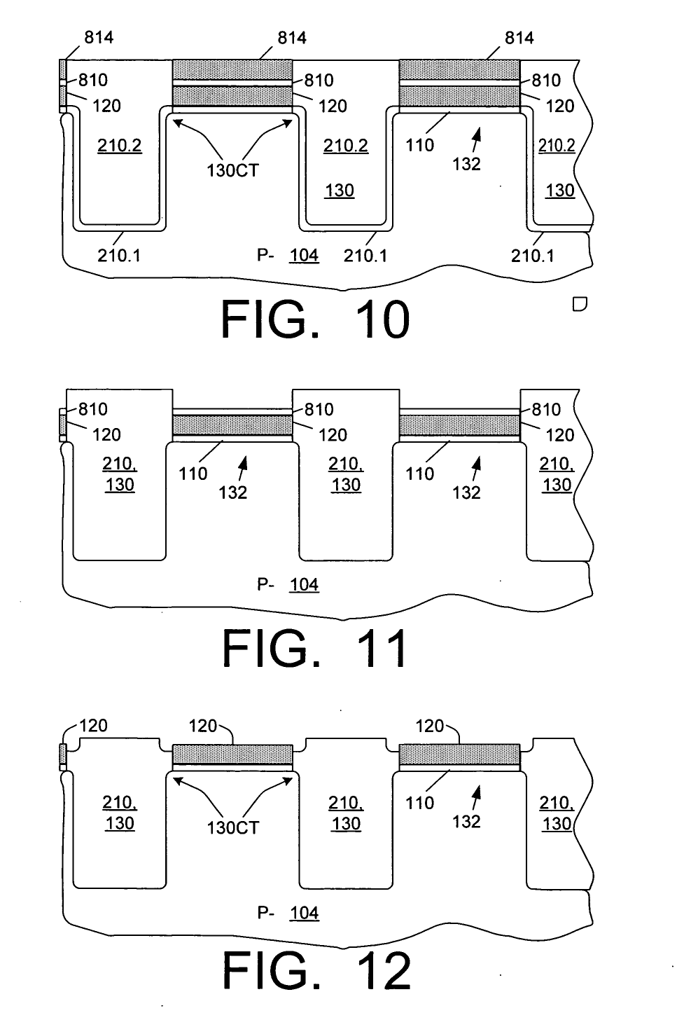

A thin silicon dioxide layer 210.1 (FIG. 9C) is thermally grown on the exposed silicon surfaces to round the edges of trenches 130. Silicon dioxide 210.2 (FIG. 10) is deposited by a high density plasma process. Oxide 210.2 fills the trenches and initially covers the nitride 120. Oxide 210.2 is polished by a CMP process that stops on nitride 814. The top surface of dielectric 210 is about even with the top surface of nitride 814.

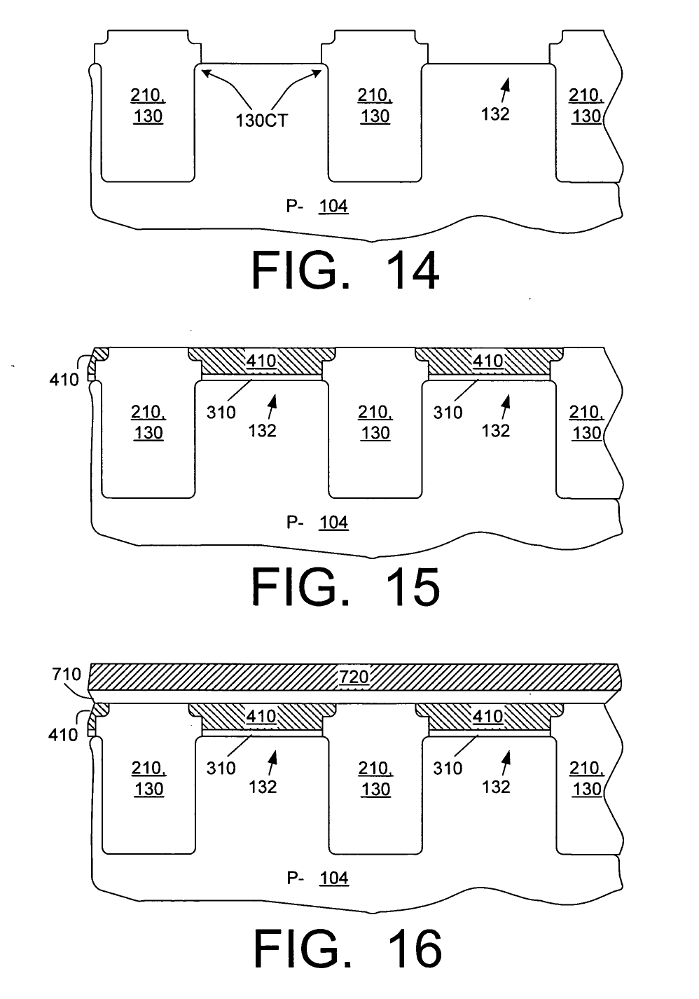

In the subsequent figures, the layers 210.1, 210.2 are shown as a single layer 210. This dielectric 210 will be referred to as STI dielectric or, more generally, field dielectric. Dielectric layers 210.1, 210.2 overlap the top trench corners 130TC. This overlap will protect the trench corners from being exposed during a subsequent removal of oxide 110. as described below in connection with FIG. 14.

Nitride 814 is removed selectively to dielectric 210 (FIG. 11). This can be done by a wet etch (e.g. with phosphoric acid).

Then dielectric 210 is etched (FIG. 12). This etch includes a horizontal component that causes the sidewalls of dielectric 210 to be laterally recessed away from areas 132. This etch can also remove the oxide 810. The etch can be an isotropic wet etch selective to silicon nitride. A buffered oxide etch or a dilute HF (DHF) etch is used in some embodiments. Nitride 120 helps to protect the dielectric 210 at trench corners 130TC during this etch.

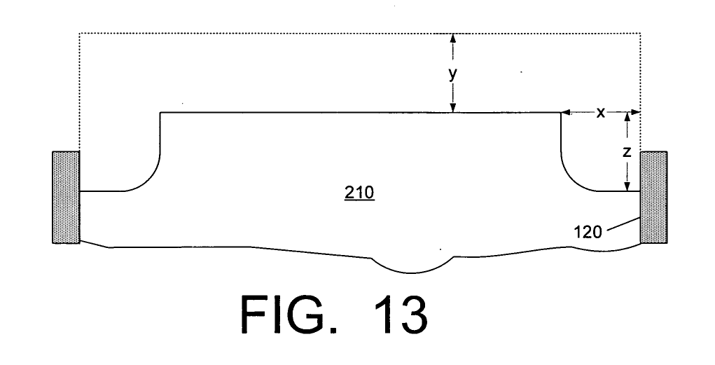

The resulting profile of dielectric 210 is a function of the etch process and the thicknesses and composition of layers 110, 120, 810, 814. FIG. 13 shows the top portion of dielectric 210 on a larger scale. The dotted line at the top marks the shape of dielectric 210 before the etch. Dimension “y” is the amount by which the dielectric 210 is etched vertically. Dimension “x” is the amount by which the sidewall is recessed horizontally at the top. Dimension “z” is the amount by which the bottom edge of the recessed sidewall portion is below the top surface of dielectric 210 at the end of the etch. The wet etch described above is isotropic, so x=y=z. The amount by which the bottom edge of the recessed sidewall is below the surface of nitride 120 is a function of the thickness of oxide 810. This amount is also a function of the etch selectivity relative to silicon nitride. The selectivity is practically infinity in some embodiments. The profile of the resulting structure is also affected by the thickness of layers 110, 120 and the etch duration. Different profiles of dielectric 210 can thus be obtained. In FIG. 13, the dielectric sidewalls curve laterally away from areas 132 as the sidewalls are traced upward.

Silicon nitride 120 and oxide 110 are removed (see FIG. 14). The etch of oxide 110 also removes a portion of oxide 210 but does not expose the trench edges 130TC even if the oxide etch is isotropic. Deterioration of oxide 210 at the trench edges could undesirably increase the leakage current at the edges. See e.g. U.S. patent application Ser. No. 10/732,616 filed by Daniel Wang et al. on Dec. 9, 2003 and incorporated herein by reference.

Turning now to FIG. 15, silicon dioxide 310 (tunnel oxide) is thermally grown on the exposed areas 132 of substrate 104. An exemplary thickness of oxide 310 is 9 nm.

Polysilicon layer 410 (floating gate polysilicon) is formed to fill the areas between dielectric regions 210 and cover the structure. Polysilicon 410 is polished by CMP until the dielectric 210 is exposed. Layer 410 is made conductive by doping. The horizontal top surface of polysilicon 410 projects over the isolation trenches 130 laterally beyond the areas 132.

Floating gates 410 abut dielectric regions 210. In FIG. 15, the floating gate sidewalls extend laterally outward beyond areas 132 as the sidewalls are traced upward. Different sidewall profiles can be obtained as defined by the sidewall profiles of dielectric 210.

Then ONO 710 (FIG. 16) is formed over the structure, and control gate polysilicon 720 is deposited and patterned. Polysilicon 720 is made conductive by doping. Layers 710, 410 can be patterned after the patterning of layer 720 as appropriate.

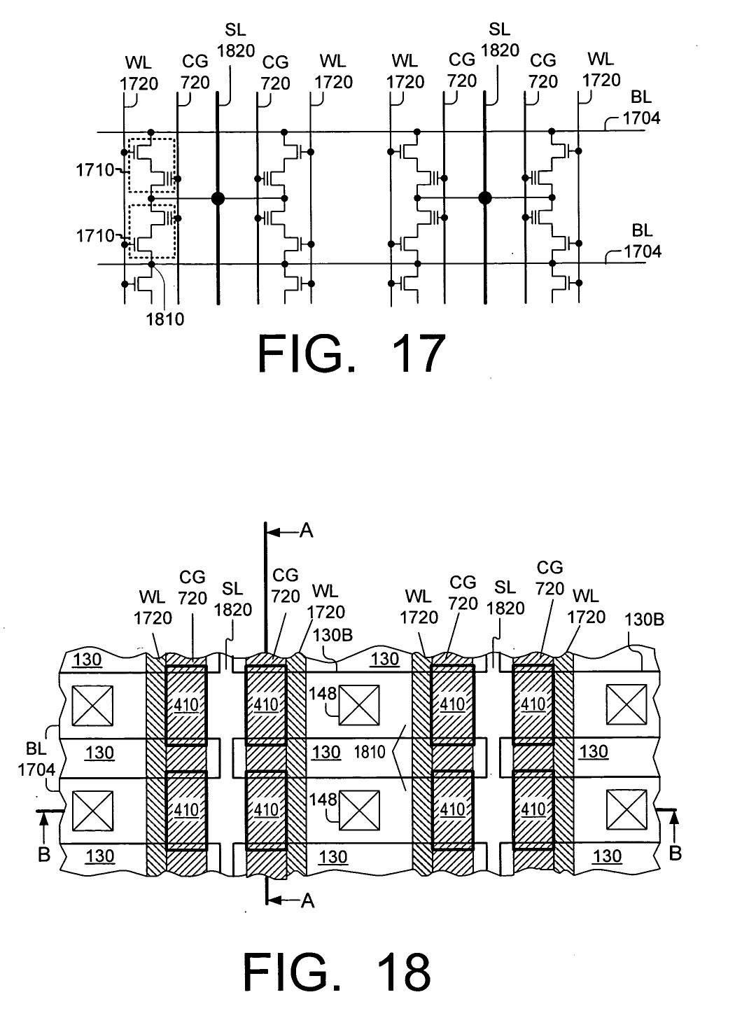

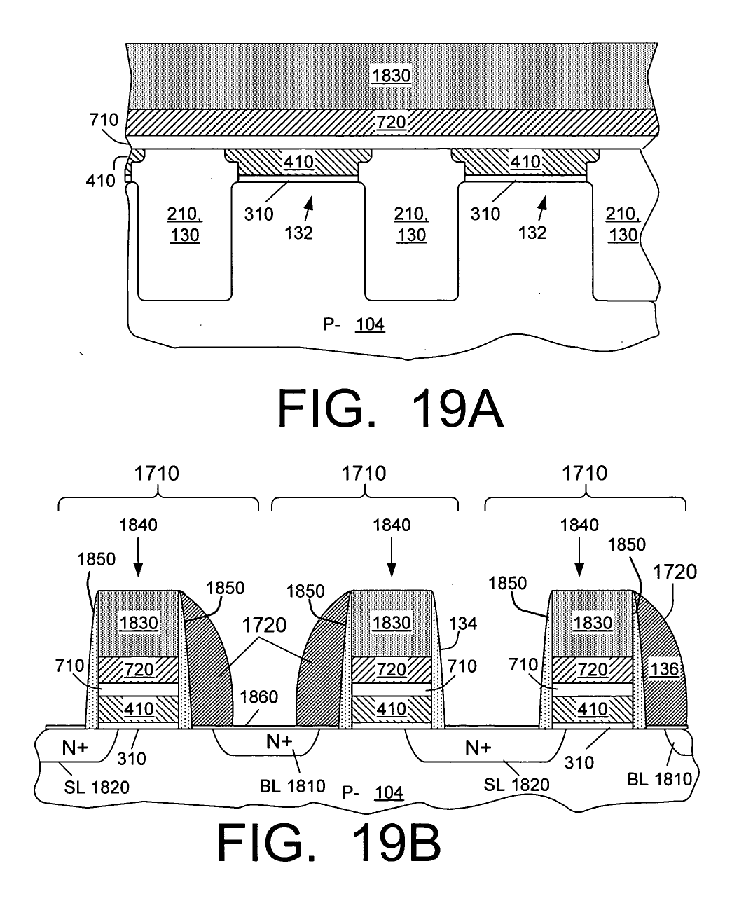

A wide range of floating gate memories can be made using the teachings of the present invention, including stacked gate, split gate and other cell structures, flash and non-flash EEPROMs, and other memory types known or to be invented. An example split gate flash memory array is illustrated in FIGS. 17, 18, 19A, 19B. This memory array is similar to one disclosed in the aforementioned U.S. Pat. No. 6,355,524 but is modified to increase the gate coupling ratio. FIG. 17 is a circuit diagram of the array. FIG. 18 is a top view. FIG. 19A is a cross section along the line A-A in FIG. 18. Line A-A passed through a control gate line 720 providing the control gates for one row of the memory cells. FIG. 19B is a cross section along the line B-B which passes through a bitline 1704 extending across the array in the column direction. Each memory cell can be erased by Fowler-Nordheim tunneling of electrons from its floating gate 410 through silicon dioxide 310 to source line 1820 or the substrate region containing the channel regions of the memory cells. The cell can be programmed by source-side hot electron injection.

Each memory cell 1710 includes a floating gate 410, a control gate 720, and a select gate 1720. The control gates lines 720 are made of doped polysilicon. The select gates for each row are provided by a doped polysilicon wordline. Wordlines 1720 and control gate lines 720 extend in the row direction across the array. In FIG. 17, each memory cell is shown schematically as a floating gate transistor and an NMOS transistor connected in parallel.

Each memory cell has source/drain regions 1810, 1820. Regions 1810 (“bitline regions” ) are adjacent to the select gates. These regions are connected to the bitlines. Regions 1820 (“source line regions”) of each row are shared with regions 1820 of an adjacent row on the opposite side of the cells from regions 1810. Regions 1820 of the two rows are merged into a diffused source line that runs in the row direction across the array.

Isolation trenches 130 are placed between adjacent columns of the array. The trench boundaries are shown at 130B in FIG. 18. Each trench runs under two adjacent rows of the array (under two control gate lines 720 and respective wordlines 1720) and terminates at source lines 1820, slightly projecting into the source lines from under the control gate lines. Floating gates 410 overlap the isolation trenches, as in FIG. 15.

Trenches 130, trench dielectric 210, tunnel oxide 310, floating gate layer 410, and dielectric 710 are manufactured as described above in connection with FIGS. 8-16. Then polysilicon 720 is deposited as described above. Silicon nitride 1830 is deposited over polysilicon 720 and patterned photolithographically to define the control gate lines 720. Layers 720, 710, 410, 310 are etched away in the areas not covered by nitride 1830. The remaining portions of nitride 1830, polysilicon 720, ONO 710, polysilicon 410, and oxide 310 form a number of stacks 1840. Each stack corresponds to one row of the array.

The remaining fabrication steps can be as in the aforementioned U.S. Pat. No. 6,355,524. Dielectric 1850 (FIG. 19B) is formed on the sidewalls of each stack to insulate the floating and control gates from the wordlines. Silicon dioxide 1860 is grown on the exposed portions of substrate 104 to provide gate dielectric for the select gates. Polysilicon 1720 is deposited and etched anisotropically without a mask over the array to form spacers on the stack sidewalls. Then a masked etch of polysilicon 1720 removes those spacers that are not used for the wordlines (the spacers over the source line regions 1820). The same mask (not shown) can be used to dope the source lines 1820. Then the mask is removed, and additional dopant is implanted to dope the source line and bitline regions 1810, 1820.

The invention is not limited to the embodiments described above. For example, pad oxide 110 (FIG. 8) can be omitted, or used as tunnel oxide 310 (FIG. 14). Oxide 810 can also be omitted; silicon nitride layers 120, 814 can be combined into a single layer. This layer can be etched at the stage of FIG. 11 with a timed etch. Alternatively, this layer can be completely removed before the etch of dielectric 210. The entire sidewall portion of dielectric 210 above substrate 104 can be laterally recessed by the etch. The invention is not limited to any particular materials or memory layouts or circuit diagrams. The invention is defined by the appended claims.

1. A method for manufacturing an integrated circuit, the method comprising:
(1) obtaining a structure comprising:
a semiconductor substrate having one or more first areas which are to include one or more active areas of one or more nonvolatile memory cells;
a first layer overlying the one or more first areas;
one or more dielectric regions abutting the one or more first areas and rising above the substrate, each of said dielectric regions having a sidewall abutting at least one of the first areas, wherein at least a top portion of the sidewall is exposed;
(2) simultaneously etching the one or more dielectric regions and the first layer, to remove the first layer and recess the top portions of the sidewalls laterally away from the adjacent first areas;
(3) forming a first conductive layer over the one or more first areas, the first conductive layer being insulated from the one or more first areas, the first conductive layer abutting the top recessed sidewall portion of each said dielectric region and providing at least a portion of a floating gate for each nonvolatile memory cell, wherein each said at least a portion of a floating gate has a horizontal top surface.

2. The method of claim 1 further comprising:
forming a second dielectric layer on the first conductive layer;
forming a second conductive layer on the second dielectric layer, to provide a control gate for each nonvolatile memory cell.

3. The method of claim 1 wherein the operation (1) comprises:
forming one or more first structures on the one or more first areas, the one or more first structures comprising the first layer and covering said top portion of each said sidewall; and
etching the one or more first structures to expose the first layer and said top portion of each said sidewall.

4. The method of claim 1 wherein the operation (1) comprises:
forming a plurality of layers including the first layer on the semiconductor substrate;
forming a mask on said plurality of layers to define the one or more first areas;
patterning said plurality of layers and the semiconductor substrate as defined by said mask, to form one or more first structures on the one or more first areas and to form trenches in the semiconductor substrate in areas in which the dielectric regions are to be formed, each first structure being a stack of said plurality of layers;
removing sidewall portions of the stacks to recess the stacks farther away from the trenches;
forming the dielectric regions, wherein each said sidewall of each said dielectric region abuts, and is covered by, one of said first structures;
etching the one or more first structures to expose the first layer and said top portion of each said sidewall.

5. The method of claim 4 wherein the dielectric regions overlap top edges of the trenches.

6. The method of claim 4 further comprising, between the operations (2) and (3):
removing said stacks; and then
forming a first dielectric layer on the one or more first areas, wherein the first conductive layer overlies and physically contacts the first dielectric layer.

7. The method of claim 6 wherein the dielectric regions overlap top edges of the trenches before and after the stacks have been removed.

8. The method of claim 7 wherein a bottom layer in said plurality of layers contacts the semiconductor substrate and comprises a material present in the dielectric regions.

9. The method of claim 4 wherein the plurality of layers further comprises a second layer over the one or more first areas, wherein the first layer overlies the second layer;
wherein in the operation (2), the first layer and the dielectric regions are etched selectively to the second layer.

10. The method of claim 1 wherein each said at least a portion of a floating gate overlies and projects laterally beyond one of the first areas and abuts at least one of said dielectric regions inside a sidewall recess formed in the operation (2).

11. The method of claim 1 further comprising forming a control gate for each nonvolatile memory cell over the semiconductor substrate; and
wherein a state of at least one memory cell is changeable by applying a voltage to the memory cell's control gate to cause an electron transfer between the memory cell's floating gate and the semiconductor substrate.

12. The method of claim 11 wherein the at least one memory cell is both programmable and erasable by an electron transfer between the memory cell's floating gate and the semiconductor substrate.

13. A method for manufacturing an integrated circuit, the method comprising:
(1) obtaining a structure comprising:
a semiconductor substrate having one or more first areas which are to include one or more active areas of one or more nonvolatile memory cells;
a first layer overlying the one or more first areas;
one or more dielectric regions abutting the one or more first areas and rising above the substrate, each of said dielectric regions having a sidewall abutting at least one of the first areas, wherein at least a top portion of the sidewall is exposed;
(2) simultaneously etching the one or more dielectric regions and the first layer, to remove the first layer and recess the top portions of the sidewalls laterally away from the adjacent first areas;
(3) forming a first conductive layer over the one or more first areas, the first conductive layer being insulated from the one or more first areas, the first conductive layer abutting the top recessed sidewall portion of each said dielectric region and providing at least a portion of a floating gate for each nonvolatile memory cell, wherein each said at least a portion of a floating gate overlies and projects laterally beyond one of the first areas into a sidewall recess formed in the operation (2).

14. The method of claim 13 further comprising:
forming a second dielectric layer on the first conductive layer;
forming a second conductive layer on the second dielectric layer, to provide a control gate for each nonvolatile memory cell.

15. The method of claim 13 wherein the operation (1) comprises:
forming one or more first structures on the one or more first areas, the one or more first structures comprising the first layer and covering said top portion of each said sidewall; and
etching the one or more first structures to expose the first layer and said top portion of each said sidewall.

16. The method of claim 13 wherein the operation (1) comprises:
forming a plurality of layers including the first layer on the semiconductor substrate;
forming a mask on said plurality of layers to define the one or more first areas;
patterning said plurality of layers and the semiconductor substrate as defined by said mask, to form one or more first structures on the one or more first areas and to form trenches in the semiconductor substrate in areas in which the dielectric regions are to be formed, each first structure being a stack of said plurality of layers;
removing sidewall portions of the stacks to recess the stacks farther away from the trenches;
forming the dielectric regions, wherein each said sidewall of each said dielectric region abuts, and is covered by, one of said first structures;
etching the one or more first structures to expose the first layer and said top portion of each said sidewall.

17. The method of claim 16 wherein the dielectric regions overlap top edges of the trenches.

18. The method of claim 16 further comprising, between the operations (2) and (3):
removing said stacks; and then
forming a first dielectric layer on the one or more first areas, wherein the first conductive layer overlies and physically contacts the first dielectric layer.

19. The method of claim 18 wherein the dielectric regions overlap top edges of the trenches before and after the stacks have been removed.

20. The method of claim 19 wherein a bottom layer in said plurality of layers contacts the semiconductor substrate and comprises a material present in the dielectric regions.

21. The method of claim 16 wherein the plurality of layers further comprises a second layer over the one or more first areas, wherein the first layer overlies the second layer;
wherein in the operation (2), the first layer and the dielectric regions are etched selectively to the second layer.

22. The method of claim 13 further comprising forming a control gate for each nonvolatile memory cell over the semiconductor substrate; and
wherein a state of at least one memory cell is changeable by applying a voltage to the memory cell's control gate to cause an electron transfer between the memory cell's. floating gate and the semiconductor substrate.

23. The method of claim 22 wherein the at least one memory cell is both programmable and erasable by an electron transfer between the memory cell's floating gate and the semiconductor substrate.

24. A method for manufacturing an integrated circuit, the method comprising:
(1) obtaining a structure comprising:
a semiconductor substrate having one or more first areas which are to include one or more active areas of one or more nonvolatile memory cells;
a first layer overlying the one or more first areas;
one or more dielectric regions abutting the one or more first areas and rising above the substrate, each of said dielectric regions having a sidewall abutting at least one of the first areas, wherein at least a top portion of the sidewall is exposed;
(2) simultaneously etching the one or more dielectric regions and the first layer, to remove the first layer and recess the top portions of the sidewalls laterally away from the adjacent first areas;
(3) forming a first conductive layer over the one or more first areas, the first conductive layer being insulated from the one or more first areas, the first conductive layer abutting the top recessed sidewall portion of each said dielectric region and providing at least a portion of a floating gate for each nonvolatile memory cell; and
forming a control gate for each nonvolatile memory cell over the semiconductor substrate;
wherein a state of at least one memory cell is changeable by applying a voltage to the memory cell's control gate to cause an electron transfer between the memory cell's floating gate and the semiconductor substrate.

25. The method of claim 24 wherein the at least one memory cell is both programmable and erasable by an electron transfer between the memory cell's floating gate and the semiconductor substrate.

26. The method of claim 24 further comprising:
forming a second dielectric layer on the first conductive layer;
forming a second conductive layer on the second dielectric layer, to provide a control gate for each nonvolatile memory cell.

27. The method of claim 24 wherein the operation (1) comprises:
forming one or more first structures on the one or more first areas, the one or more first structures comprising the first layer and covering said top portion of each said sidewall; and
etching the one or more first structures to expose the first layer and said top portion of each said sidewall.

28. The method of claim 24 wherein the operation (1) comprises:
forming a plurality of layers including the first layer on the semiconductor substrate;
forming a mask on said plurality of layers to define the one or more first areas;
patterning said plurality of layers and the semiconductor substrate as defined by said mask, to form one or more first structures on the one or more first areas and to form trenches in the semiconductor substrate in areas in which the dielectric regions are to be formed, each first structure being a stack of said plurality of layers;
removing sidewall portions of the stacks to recess the stacks farther away from the trenches;
forming the dielectric regions, wherein each said sidewall of each said dielectric region abuts, and is covered by, one of said first structures;
etching the one or more first structures to expose the first layer and said top portion of each said sidewall.

29. The method of claim 28 wherein the dielectric regions overlap top edges of the trenches.

30. The method of claim 28 further comprising, between the operations (2) and (3):
removing said stacks; and then
forming a first dielectric layer on the one or more first areas, wherein the first conductive layer overlies and physically contacts the first dielectric layer.

31. The method of claim 30 wherein the dielectric regions overlap top edges of the trenches before and after the stacks have been removed.

32. The method of claim 31 wherein a bottom layer in said plurality of layers contacts the semiconductor substrate and comprises a material present in the dielectric regions.

33. The method of claim 28 wherein the plurality of layers further comprises a second layer over the one or more first areas, wherein the first layer overlies the second layer;
wherein in the operation (2), the first layer and the dielectric regions are etched selectively to the second layer.
